(19) United States
(12) Patent Application Publication
(10) Pub. No.: US 2020/0243709 A1
(43) Pub. Date: Jul. 30, 2020

(54) METHOD FOR PRODUCING AN OPTOELECTRONIC SEMICONDUCTOR CHIP, AND OPTOELECTRONIC SEMICONDUCTOR CHIP

(71) Applicant: OSRAM OLED GmbH, Regensburg (DE)

(72) Inventor: Xue WANG, Regensburg (DE)

(21) Appl. No.: 16/755,101

(22) PCT Filed: Sep. 21, 2018
(86) PCT No.: PCT/EP2018/075616

§ 371 Date: Apr. 9, 2020

(30) Foreign Application Priority Data
Oct. 10, 2017 (DE) 10 2017 123 542.6

(51) Int. Cl. H01L 33/00; H01L 33/30; H01L 33/14; H01L 33/42; C23C 16/30; C30B 25/16; C30B 29/40; C30B 29/44

(52) U.S. Cl. CPC H01L 33/0062; H01L 33/305; H01L 33/14; H01L 33/0025; C30B 29/44; C23C 16/301; C30B 25/16; C30B 29/40; H01L 33/42

(57) ABSTRACT

The invention relates to a method for producing an optoelectronic semiconductor chip (100) comprising the steps:
A) providing a surface (2) in a chamber (5),
B) providing at least one organic first precursor (3) and one second precursor (4) in the chamber (5), wherein the organic first precursor (3) comprises a gaseous III-compound material (3), wherein the second precursor (4) comprises a gaseous phosphorus-containing compound material (41),
C) epitaxial deposition of the first and the second precursor (3, 4) at a temperature between 540° C. inclusive and 660° C. inclusive and a pressure between 30 mbar inclusive and 300 mbar inclusive onto the surface (2) in the chamber (5) to form a first layer (12), comprising a phosphide compound semiconductor material (6), wherein the ratio between the second and the first precursor (3, 4) is between 5 inclusive and 200 inclusive, wherein the phosphide compound semiconductor material (6) produced is doped with carbon, wherein the carbon doping concentration is at least 4×10¹⁹ cm⁻³.

The invention relates to a method for producing an optoelectronic semiconductor chip. Furthermore, the invention relates to an optoelectronic semiconductor chip which is preferably produced by the method described herein.

For optoelectronic semiconductor chips based on phosphide compound semiconductor materials, AlGaAs layers are often used for current spreading and/or contacting on the p-side. However, these layers can corrode, which can lead to failure of the semiconductor chip. In addition, such layers show a comparatively high absorption for the light to be generated in the semiconductor chip. Alternatively, gallium phosphide doped with magnesium can be used. Although this avoids susceptibility to moisture, it achieves a significantly worse specific resistance than AlGaAs. In addition, magnesium can diffuse into the active region and form defects, which leads to a loss of light.

One object of the invention is to provide a semiconductor chip that has a good current spreading and/or contacting with simultaneously low absorption losses and a high moisture stability. In particular, the semiconductor chip is to be produced simply and/or cheaply by the method described here.

This object is or these objects are solved, inter alia, by a method for producing an optoelectronic semiconductor chip according to claim 1 and an optoelectronic semiconductor chip according to claim 17. Advantageous embodiments and further developments of the invention are the subject of the dependent claims.

In at least one embodiment, the method for producing an optoelectronic semiconductor chip comprises the steps:

A) providing a surface in a chamber,

B) providing at least one organic first precursor and one second precursor in the chamber. The organic first precursor comprises or consists of a gaseous III-compound material. The second precursor comprises or consists of a gaseous phosphorous-containing compound material.

C) epitaxial deposition of the first and the second precursor onto the surface in the chamber. This forms a first layer comprising or consisting of a phosphide compound semiconductor material. The epitaxial deposition is performed at a temperature between 540° C. inclusive and 660° C. inclusive and a pressure between 30 mbar inclusive and 300 mbar inclusive, wherein the ratio between the second and the first precursor is between 5 inclusive and 200 inclusive, wherein the phosphide compound semiconductor material produced is doped with carbon wherein the carbon doping concentration is at least 2×10¹⁹ cm⁻³ or at least 4×10¹⁹ cm⁻³.

The invention further relates to an optoelectronic semiconductor chip. Preferably, the optoelectronic semiconductor chip is produced by the method described here. In this context, all definitions and embodiments of the method for producing an optoelectronic semiconductor chip also apply to the optoelectronic semiconductor chip and vice versa.

In at least one embodiment, the optoelectronic semiconductor chip comprises a semiconductor layer sequence. The semiconductor layer sequence comprises in particular a phosphide compound semiconductor material. The semiconductor layer sequence comprises an active region provided for generating radiation, an n-conducting region and a p-conducting region. The active region is arranged between the n-conducting region and the p-conducting region. The p-conducting region comprises a first layer, or the first layer adjoins, in particular directly, the p-conducting region. The first layer is based on the carbon doped phosphide compound semiconductor material. The carbon doping concentration of the phosphide compound semiconductor material is at least 5×10¹⁹ cm⁻³. The first layer can be formed as a p-contact layer and/or p-current spreading layer.

According to at least one embodiment, the method for producing an optoelectronic component comprises the method step A), providing a surface. The surface is provided in a chamber. The chamber is in particular a component of an epitaxial system. Preferably, the chamber is part of a system for metal-organic vapor phase epitaxy (MOVPE).

According to at least one embodiment, the surface is the surface of a substrate or carrier. For example, the substrate can be a GaAs, sapphire or silicon wafer.

Additionally or alternatively, the surface is the surface of a semiconductor layer sequence. The semiconductor layer sequence is provided for the generation of radiation, in particular over the active region. The semiconductor layer sequence comprises an n-conducting region and a p-conducting region. The active region is arranged between the n-conducting region and the p-conducting region.

The active region is provided in particular for generating radiation in the blue, green, yellow, red, infrared and/or UV spectral range.

According to at least one embodiment, the active region of the semiconductor layer sequence is based on a phosphide compound semiconductor material. Alternatively or additionally, the first layer can be based on or consist of a phosphide compound semiconductor material.

“Based on phosphide compound semiconductor material” means in the present context that the material comprises or consists of a phosphide compound semiconductor material, preferably AlₓIn_{y}Ga_{1-x-y}P, wherein 0≤x≤1, 0≤y≤1 and x+y≤1. Preferably, for the first layer x=0 and y=0. In this context, this material does not necessarily have a mathematically exact composition according to the above formula. Rather, it may, for example, have one or more dopants and additional components. For simplicity's sake, however, the above formula only includes the essential components of the crystal lattice (Al, Ga, In, P), even if these may be partially replaced and/or supplemented by small amounts of other substances.

In particular, the semiconductor layer sequence comprises several layers of gallium phosphide.

The active layer can, for example, be designed as a pn junction, as a double heterostructure, as a single quantum well structure, or as a multiple quantum well structure. The term quantum well structure covers any structure in which charge carriers undergo quantization of their energy states by confinement. In particular, the term quantum well structure does not contain any information about the dimensionality of the quantization. It therefore includes quantum wells, quantum wires or quantum dots and any combination of these quantum structures.

According to at least one embodiment, the method comprises a step B), providing at least one organic first precursor and one second precursor in the chamber. The organic first precursor comprises or consists of a gaseous III-compound material. The second precursor comprises or consists of a gaseous phosphorus-containing compound material.

According to at least one embodiment, the organic first precursor and/or the III-compound material is trimethylgallium (TMGa), trimethylindium (TMIn) or trimethylaluminium (TMAl). Preferably, the organic first precursor and/or the III-compound material is trimethylgallium.

According to at least one embodiment, the second precursor and/or the phosphorus-containing compound material are phosphine (PH₃).

According to at least one embodiment, the method comprises a step C), epitaxial deposition of the first and the second precursor onto the surface in the chamber. This forms a first layer. The first layer comprises or consists of the C-doped phosphide compound semiconductor material, preferably C-doped GaP. The epitaxial deposition is carried out at a temperature between 540° C. inclusive and 660° C. inclusive or 700° C. and a pressure between 30 mbar inclusive and 300 mbar inclusive, wherein the ratio between the second and first precursor is between 5 inclusive and 200 inclusive (second precursor/first precursor=5 to 200). The carbon doping concentration is at least 5×10¹⁹ cm⁻³.

According to at least one embodiment of the semiconductor chip, the p-conducting region comprises a p-current spreading layer. The p-current spreading layer is in particular part of the semiconductor layer sequence. The p-current spreading layer is formed in particular on the side of the p-conducting region facing away from the active region. For example, the p-current spreading layer forms the first layer produced in step C) of the method, which comprises the C-doped phosphide compound semiconductor material.

Alternatively or additionally, a current spreading layer comprising a transparent conductive oxide adjoins the p-conducting region of the semiconductor layer sequence. A metallic p-connecting contact is arranged on the current spreading layer, which adjoins the current spreading layer at least in some regions. The p-connecting contact comprises a metal or a metal alloy and is arranged on a side of the current spreading layer facing away from the semiconductor layer sequence.

The metallic p-connecting contact is used in particular to supply current through a current spreading layer into the n-conducting region. However, it can also have the function of a mirror layer at the same time. In particular, the first layer produced in step C), which in particular comprises a phosphide compound semiconductor material, is arranged between the current spreading layer formed of a transparent conductive oxide and the p-conducting region.

In particular, the first layer is formed of carbon-doped gallium phosphide. The first layer serves here in particular as a p-contact layer. The p-contact layer is advantageously very highly doped with carbon. The carbon doping concentration of the phosphide compound semiconductor material of the first layer is in particular 5·10¹⁹ cm⁻³ to 1·10²¹ cm⁻³, in particular for a first layer formed as a p-contact layer. Preferably, the concentration is 5·10²⁰ cm⁻³. Furthermore, the p-contact layer is a comparatively thin layer whose thickness is preferably between 5 nm and 200 nm, in particular between 10 nm and 35 nm, for example 20 nm.

According to at least one embodiment, the first layer is formed as a p-contact layer. Preferably, the first layer formed as a p-contact layer is produced in step C) at a temperature between 520° C. inclusive or 540° C. and 620° C. inclusive (real temperature), in particular between 540° C.-580° C. inclusive, for example 560° C., and a pressure of 30 mbar to 300 mbar, in particular at a pressure between 40-90 mbar, for example 66 mbar, and a ratio of the second precursor material to the first precursor material of 5 to 150, in particular 10-50, for example 15.

According to at least one embodiment, a first layer formed as a p-contact layer is produced in an epitaxial system, for example VECCO E450, K450, K475 or K475i or Aixtron G4 or G5. A temperature between 560° C. and 600° C. can be selected, for example 560° C. and/or 600° C. A pressure of 66 mbar, for example, can be selected. The ratio of second precursor to first precursor can be 25 at 600° C. and/or 16 at 560° C. The first precursor can be trimethylgallium and the second precursor phosphine. In particular, hydrogen can be used as a carrier gas in step C). The produced layer thickness of the first layer is in particular between 5 nm and 35 nm. The surface can rotate in the chamber, wherein the rotation has, for example, a revolution of 500 rpm and/or 700 rpm. Thus, an optoelectronic semiconductor chip can be produced with a first layer that comprises a high carbon doping in the phosphide compound semiconductor material. In particular, the carbon doping concentration of the produced phosphide compound semiconductor material of the first layer is between 5×1019 cm−3 inclusive and 1×10²¹ cm⁻³. The optoelectronic semiconductor chip has a contact resistance ITO/GaP between 1×10⁻⁵ to 1×10⁻⁴ Ω·cm², for gold/gallium phosphide of approximately 2×10⁻⁵ Ω·cm² and for platinum gold/gallium phosphide of approximately 7×10⁻⁶ Ω·cm².

According to at least one embodiment, the first layer is formed as a current spreading structure. In particular, a first layer formed as a p-current spreading structure is produced in step C) at a temperature between 560° C. and 660° C. (real temperature), in particular 580° C.-620° C., for example 600° C., and a pressure of 30 mbar to 300 mbar, in particular 40-90 mbar, for example 66 mbar, and a ratio between second precursor and first precursor of 10 to 200, in particular 10-40, for example 24.

According to at least one embodiment, the temperature in step C) is between 540° C. and 620° C. for a first layer formed as a p-contact layer or between 560° C. and 660° C. for a first layer formed as a p-current spreading layer.

For example, a first layer formed as a p-current spreading layer can be produced in an epitaxial system, for example by VECCO E450, K450 and K475. A temperature of 600° C., a pressure of 66 mbar and a ratio of second precursor to first precursor of 25 can be selected. Trimethylgallium and phosphine can be used as precursors. A first layer comprising the phosphide compound semiconductor material with a carbon doping concentration of 2×10¹⁹ cm⁻³ or 4×10¹⁹ cm⁻³ to 3×10²⁰ cm⁻³ can be produced. The thickness of the first layer can be between 200 nm and 350 nm, for example 270 nm. The surface can be rotated with a revolution of 500 rpm and/or 750 rpm. The produced optoelectronic semiconductor chip can comprise a specific resistance of 0.002 to 0.006 Ω·cm and comprise a contact resistance gold/gallium phosphide between 5×10⁻⁶ and 2×10⁻⁴ Ω·cm².

The inventor has recognized that by the method described here, in particular by combining the method parameter window given in step C), an optoelectronic semiconductor chip with a first layer of the phosphide compound semiconductor material with a high carbon concentration can be produced. In particular, the carbon doping concentration is at least 4×10¹⁹ cm⁻³ or at least 2×10¹⁹ cm⁻³. It is precisely the combination of temperature, pressure and the ratio between the second and first precursor which produces a first layer.

In addition, the first layer has a low layer thickness and is moisture stable and resistant to delamination. This is an advantage in contrast to the previously known magnesium-doped gallium phosphide, which must be formed as a thick layer and has a low contact resistance, and the previously known gallium aluminum arsenide, which has a high absorption and a high delamination.

According to at least one embodiment, a carrier gas is used in step C). In particular, hydrogen is used as the carrier gas. In particular, no argon is used as the carrier gas. The carrier gas is preferably used to transport the gaseous III- and/or phosphorus-containing compound materials into the chamber. The first and the second precursors then already partly react in the gas phase and diffuse to the surface where the precursors absorb and a decomposition reaction takes place. The gaseous products desorb and diffuse away from the chamber.

In particular, the precursors are free of impurities that may be introduced into the precursors during production. The decomposition of the III-compound material is preferably carried out in several stages in which the methyl groups are successively eliminated as radicals in the gas phase. The last decomposition step of the monomethyl group III-element then takes place on the surface with the participation of the phosphorus-containing compound material. This produces nascent atomic hydrogen during its decomposition, which then reacts with the last methyl group to form methane. Methane can then be removed as a by-product. The carrier gas determines in particular the hydrodynamics of the gas phase and can influence the reaction if it occurs as educt or product in the reaction.

According to at least one embodiment, the epitaxial deposition in step C) is a metal-organic vapor phase epitaxy (MOVPE). Metalorganic vapor phase epitaxy can also be called organometallic vapor phase epitaxy (OMVPE) or metalorganic chemical vapor deposition (MOCVD). The principle procedure of metalorganic vapor phase epitaxy is sufficiently well known to a person skilled in the art and will therefore not be explained in detail here.

According to at least one embodiment, an additional precursor, a gaseous organic third precursor, is used. The third precursor is preferably formed from CBr₄. The third precursor serves to increase the carbon doping concentration in the first layer.

According to at least one embodiment, the first layer comprises a thickness of 5 nm inclusive to 200 nm inclusive. Alternatively, the first layer comprises a layer thickness of 50 nm inclusive to 500 nm inclusive, in particular of 200 nm inclusive to 350 nm inclusive. In particular, the thickness of the first layer is between 5 and 200 nm if the first layer is formed as a p-contact layer. In particular, the thickness of the first layer is between 50 nm and 500 nm when the first layer is formed as a p-current spreading layer.

According to at least one embodiment, the temperature in step C) has a value between 560° C. and 600° C., for example 600° C.

According to at least one embodiment, the pressure in step C) has a value between 60 mbar and 70 mbar, for example 66 mbar.

According to at least one embodiment, the carbon doping concentration has a value between 1·10²⁰ cm⁻³ and 5·10²⁰ cm⁻³ or between 5·10¹⁹ cm⁻³ and 3·10²⁰ cm⁻³.

According to at least one embodiment, the temperature and/or pressure in step C) are constant. In other words, there is no temperature and/or pressure ramp during method step C).

According to at least one embodiment, the ratio between the second and first precursor is between 5 inclusive and 150 inclusive. Alternatively, the ratio between the second and first precursor is between 10 inclusive and 200 inclusive. The ratio between 5 inclusive and 150 inclusive is preferably present in a first layer formed as a p-contact layer. The ratio between 10 and 200 inclusive is preferably present in a first layer formed as a p-current spreading layer.

According to at least one embodiment, the phosphide compound semiconductor material is a gallium phosphide.

According to at least one embodiment, the phosphide compound semiconductor material is an aluminum gallium phosphide.

According to at least one embodiment, the first layer directly adjoins the surface of a semiconductor layer sequence. The first layer is preferably formed as a p-contact layer and/or as a p-current spreading layer.

According to at least one embodiment, a cooling step is performed after step C). In this cooling step at least the phosphide compound semiconductor material is cooled in the chamber. In particular, the chamber is free of the second precursor material.

According to at least one embodiment, a cooling step without second precursor, in particular without a phosphide compound, and only with a carrier gas, for example hydrogen, is performed after step C).

After the epitaxial growth of, for example, carbon-doped gallium phosphide, the surface, for example the epi disks, is cooled in the chamber of the reactor without phosphine. This avoids carbon-hydrogen passivation, which leads to a high U_{F} of, for example, 30 mV to 50 mV.

After the usual epitaxial process, the surface, for example the epi disks, is cooled under the second precursor, for example in the presence of phosphine, AsH₃ or NH₃, as it avoids desorption from the epi surface.

In the case with the gallium phosphide surface, desorption during cooling without phosphine is not observed. Therefore, no aging effect is observed. In other words, it is unusual to perform the cooling process without the second precursor, since it is known that the first layer is stabilized in the presence of the second precursor. The inventor has recognized that the absence of the second precursor in the cooling step prevents carbon-hydrogen passivation and thus reduces a high U_{F}.

According to at least one embodiment, a first layer formed as a p-contact layer comprises a high carbon doping of 1·10²⁰ cm⁻³ to 5·10²⁰ cm⁻³ and an absorption coefficient of 600 cm⁻¹ to 2000 cm⁻¹. A lower contact resistance and a high brightness of the semiconductor chip are produced. The contact resistance is well below the values described in the previous literature for ITO/GaP 1·10⁻⁵ to 1·10⁻⁴ Ωcm², Au/GaP of approximately 2·10⁻⁵ Ωcm², PtAu/GaP of approximately 7·10⁻⁶ Ωcm².

According to at least one embodiment, a first layer formed as a p-current spreading layer comprises a high carbon doping of 4·10¹⁹ to 3·10²⁰ cm⁻³ with a low specific resistance of 0.002 to 0.006 Ω·cm² and an absorption parameter in the range of 400 to 650 cm⁻¹. In comparison to the current spreading layer of, for example, AlGaAs:C, carbon-doped gallium phosphide has a better moisture stability and adhesion and thus a smaller or comparable absorption. Compared to the current spreading layer of magnesium-doped gallium phosphide, carbon-doped gallium phosphide does not have magnesium doping, thus significantly reducing the risk of aging.

So far, no method for producing an optoelectronic semiconductor chip is known which uses a combination of the method parameters described here, such as temperature, pressure and ratio values, during epitaxial deposition to produce the first layer. Thus, a phosphide compound semiconductor material layer highly doped with carbon can be produced, which is also moisture stable and has a high absorption.

So far, for example, only methods using lower temperatures of, for example, 470° C. and a pressure of 50 mbar with hydrogen carrier gas are known (Japanese Journal of Appl. Phys. Vol. 47, No. 9, 2008, pages 7023 to 7025). However, the carbon-doped phosphide compound semiconductor material layer produced therein comprises a lower carbon concentration of 3.2·10¹⁹ cm⁻³. The Journal of Electrochemical Society, Vol. 157, No. 4, 2010, pages H459 to H462 also describes a carbon-doped phosphide compound semiconductor material layer with a concentration greater than 1·10¹⁹ cm⁻³. However, these layers are produced at a lower temperature of 530° C. with a ratio of second precursor to first precursor of 11 with hydrogen carrier gas.

According to at least one embodiment, the carbon doping in the phosphide compound semiconductor material functions as a p-doping. In other words, the carbon doping functions as an acceptor. For example, the carbon is incorporated at the group V lattice sites, in particular at phosphorus lattice sites.

It has been found that the method described here can be used to produce a semiconductor chip that has improved moisture stability and lower absorption losses and further a high conductivity and thus an efficient current spreading.

Carbon is characterized by a particularly low diffusion within the semiconductor layer sequence. The risk of damage with the semiconductor layer sequence, in particular to the active region, due to diffusion of the carbon into the active region and the associated light loss of the semiconductor layer sequence is efficiently avoided.

With regard to the design of the semiconductor chip, reference is made to the claims and figures of DE 10 2017 101 637.6 and DE 10 2017 104 719.0, the disclosure content of which is hereby incorporated by reference.

According to at least one embodiment, the first layer is free of magnesium.

Further advantageous embodiments and further developments result from the exemplary embodiments described in the following.

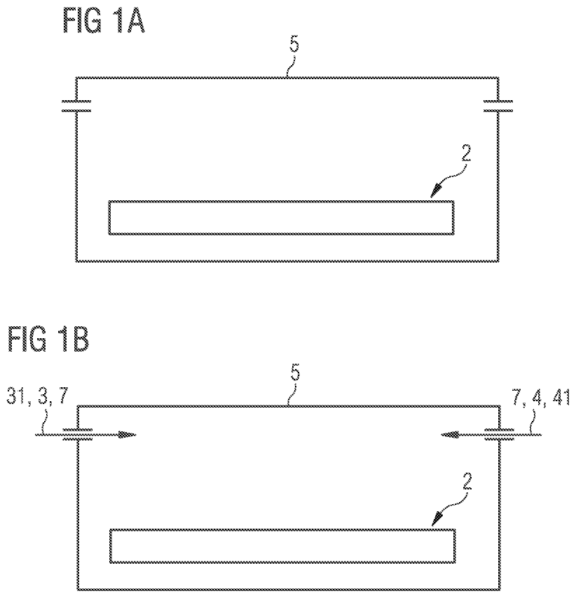

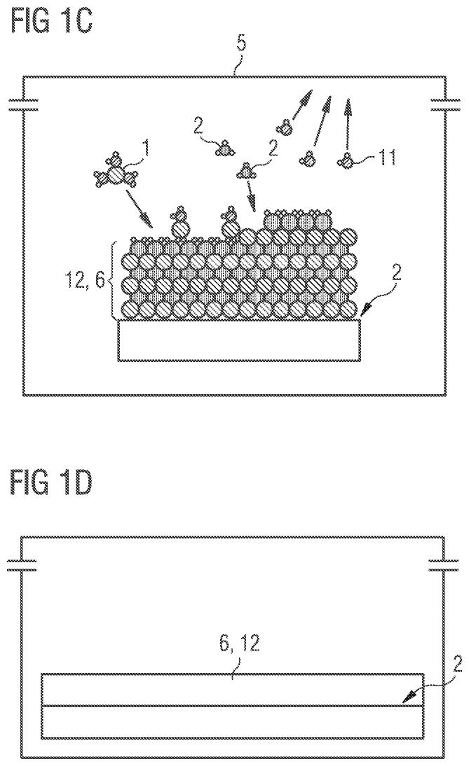

FIGS. 1A to 1D show a method for producing an optoelectronic semiconductor chip according to an embodiment,

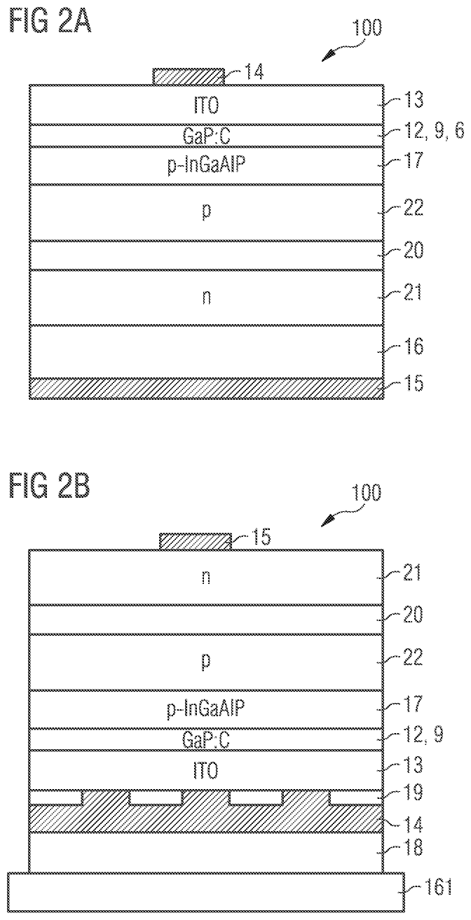

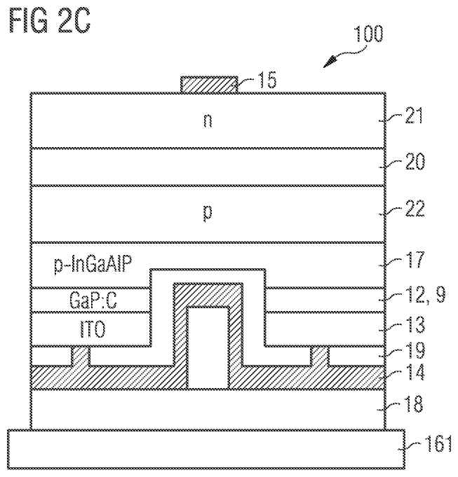

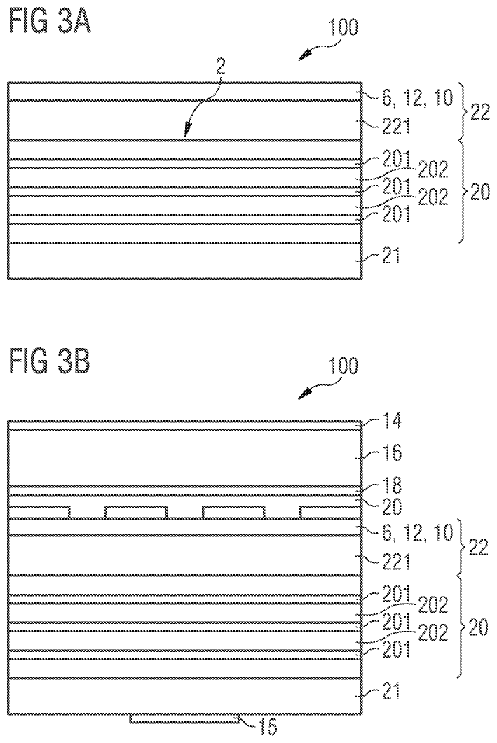

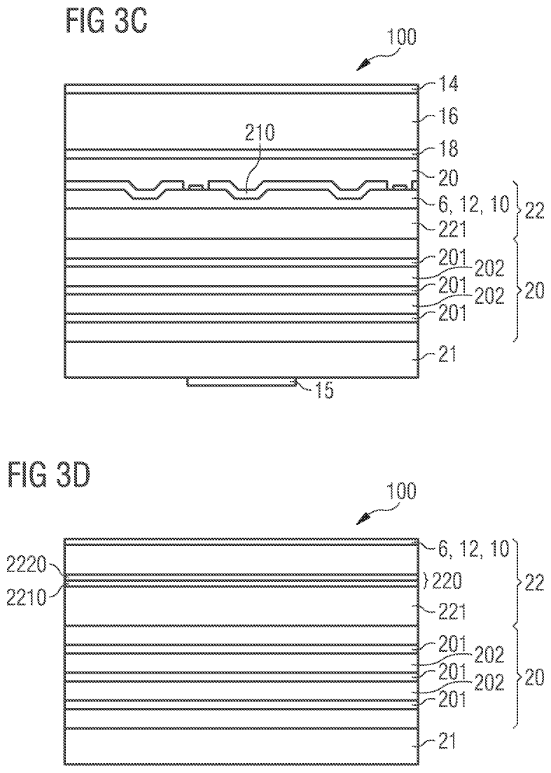

FIGS. 2A to 3D each show a schematic side view of an optoelectronic semiconductor chip according to an embodiment.

In the exemplary embodiments and figures, the same, similar and similar-acting elements can each be provided with the same reference signs. The depicted elements and their proportions among each other are not to be regarded as true to scale. Rather, individual elements, such as layers, components, parts and areas, may be shown in exaggerated size for better representability and/or better understanding.

FIGS. 1A to 1D show a method for producing an optoelectronic semiconductor chip according to an embodiment.

FIG. 1A shows providing a surface in a chamber 5. For example, chamber 5 is part of an epitaxial reactor such as VECCO K475. Surface 2 is preferably a surface of a semiconductor layer sequence 1. The semiconductor layer sequence 1 preferably comprises a phosphide compound semiconductor material. Semiconductor layer sequence 1 is provided for generating radiation. Semiconductor layer sequence 1 comprises an active region 20, which is arranged between an n-conducting region 21 and a p-conducting region 22 (not shown here).

FIG. 1B shows method step B, providing at least one organic first precursor 3 comprising a gaseous III-compound material 31 and a second precursor 4 comprising a gaseous phosphorus-containing compound material 41. The first precursor 3 may be, for example, trimethylgallium and the second precursor 4 may be, for example, phosphine. In addition, a carrier gas 7, for example hydrogen, can be used to transport the gaseous precursors 3, 4 into the chamber.

The precursors 3, 4 then partly react already in the gas phase and diffuse to surface 2. In particular, surface 2 is heated. The precursors 3, 4 are absorbed, thereby forming a first layer 12, which comprises or consists of a phosphide compound semiconductor material 6. In particular, the phosphide compound semiconductor material 6 is gallium phosphide (see FIG. 1C).

The epitaxial deposition of the phosphide compound semiconductor material of the first layer 12 in FIG. 1C is performed at a temperature between 520° C. inclusive or 540° C. and 660° C. inclusive, a pressure between 30 mbar inclusive and 300 mbar inclusive and a ratio between the second and first precursor between 5 inclusive and 200 inclusive. With the parameter window given, the surface quality is good, the conductivity high and the absorption low.

For example, methane can leave chamber 5 as by-product 11.

FIG. 1D shows the first layer 12, which comprises or consists of the C-doped phosphide compound semiconductor material 6. The carbon doping concentration comprises a value of at least 5∴10¹⁹ cm⁻³. The first layer 12 is arranged on the surface 2.

FIGS. 2A to 2D each show a schematic side view of an optoelectronic semiconductor chip according to an embodiment. In these exemplary embodiments, the first layer 12 is preferably formed as a p-contact layer.

FIG. 2A shows a schematic side view of an optoelectronic semiconductor chip 100 according to an embodiment. The semiconductor chip 100 comprises a semiconductor layer sequence 1, preferably comprising a phosphide compound semiconductor material 6. The semiconductor layer sequence 1 is provided for generating radiation. The semiconductor layer sequence 1 comprises an active region 20, which is arranged between a p-conducting region 22 and an n-conducting region 21.

The p-conducting region 22 comprises a first layer 12, or the first layer 12 adjoins, preferably directly, the p-conducting region 22. The first layer 12 comprises a carbon-doped phosphide compound semiconductor material 6, preferably carbon-doped gallium phosphide with a carbon doping concentration of at least 5×10¹⁹ cm⁻³. In this case, the first layer 12 is formed as a p-contact layer 9. The p-contact layer 9 is arranged between a p-doped indium gallium aluminum phosphide (p-InGaAlP) layer. The p-contact layer 9 adjoins a current spreading layer 13. The p-contact layer 9 can form the outermost semiconductor layer of the p-side of the optoelectronic semiconductor chip 100.

The current spreading layer 13 contains a transparent conductive oxide, for example ITO. Alternatively, the transparent conductive oxide can be zinc oxide or IZO, for example. The current spreading layer 13 adjoins a p-connecting contact made of a metal or metal alloy.

The p-connecting contact 14 is used as an electrical contact to conduct an electric current into the semiconductor layer sequence 1. An n-connecting contact 15 is used for electrical contacting from the n-side and can be arranged on the back side of a carrier 16, for example. In particular, the re-connecting contact 15 is arranged on the back side of a carrier 16 if an electrically conductive carrier is used. Alternatively, however, other arrangements of the n-connecting contact 15 are also possible.

Here, the current spreading layer 13 has the advantage that, due to its high transparency, it can be applied to the entire p-contact layer 9, which results in good current spreading without significant absorption losses. The thickness of the current spreading layer 13 is preferably between 10 nm and 300 nm, for example about 60 nm.

The p-contact layer 9 is advantageously formed as a thin layer with only less than 100 nm, preferably 1 nm to 35 nm.

Such a small thickness of the p-contact layer 9 is possible in particular because the current spreading already takes place in the adjoining current spreading layer 13 of the transparent conductive oxide. The p-contact layer 9, made of carbon-doped gallium phosphide, therefore does not need to be used for current spreading. In contrast to conventional light-emitting diode chips, in which one or more comparatively thick p-type semiconductor layers are usually used for current spreading, the very thin p-contact layer 9 has the advantage that the absorption is merely very low.

Furthermore, the thin p-contact layer 9 is characterized by a low roughness. The rms-surface roughness of the p-contact layer 9 at the interface to the current spreading layer 13 is advantageously less than 2 nm. The low roughness is made possible in particular by the low thickness, since the p-contact layer 9 is essentially not yet completely relaxed at such a low layer thickness. In other words, the p-contact layer 9 is grown strained on the underlying semiconductor layer sequence 1. A transition to the lattice constant of the gallium phosphide semiconductor material would only occur at a greater layer thickness through the formation of dislocations.

In particular, the p-contact layer 9 is free of aluminum. A high aluminum content of the p-contact layer 9 would in itself have the advantage that the absorption is low due to the large electronic band gap caused by the high aluminum content. On the other hand, it has been shown that a semiconductor layer with a high aluminum content is comparably sensitive to moisture. Since the absorption of the p-contact layer 9 described here is already very low due to the small layer thickness, the semiconductor material of the p-contact layer 9 can be advantageously free of aluminum without significant absorption occurring in the p-contact layer 9.

The doping of the p-contact layer 9 with carbon has the advantage that a diffusion of the conventionally used dopant magnesium into deeper lying semiconductor layers, in particular the active region 20, does not occur. The problem of diffusion is less of a problem when using carbon as a dopant than when using magnesium.

FIG. 2B shows a schematic side view of an optoelectronic semiconductor chip 100 according to an embodiment. The optoelectronic semiconductor chip 100 is here formed as a so-called thin-film LED. In the thin-film LED, the semiconductor layer sequence 1 is detached from its original growth substrate. On the side opposite the original growth substrate, the semiconductor chip 100 is arranged on a carrier substrate 161 with at least one connection layer 18, for example, a solder layer. Viewed from the active area 20, the p-contact layer 9 thus faces the carrier substrate 161. The carrier substrate 161 may, for example, comprise a semiconductor material, such as silicon, germanium, molybdenum or a ceramic.

As already described in conjunction with FIG. 2A, the semiconductor chip 100 of FIG. 2B contains a p-contact layer 9 with carbon-doped gallium phosphide and adjoins the current spreading layer 13, which contains a transparent conductive oxide such as ITO.

In this context, all the explanations on the p-contact layer 9 in FIG. 2B also apply as already described in conjunction with FIG. 2A.

The p-connecting contact 14 can be made of silver or gold. Silver or gold are characterized by a high reflectivity. In the example shown here, a dielectric layer 19, which can be a silicon oxide layer in particular, is arranged in some regions between the current spreading layer 13 and the p-connecting contact 14. Due to the comparatively low refractive index of the dielectric material of the dielectric layer 19, the dielectric layer 19 can cause a total reflection of part of the radiation emitted in the direction of the carrier substrate 161 towards the radiation emission surface.

Other advantageous configurations and the resulting advantages of the exemplary embodiment in FIG. 2B correspond to the explanations for FIG. 2A and are therefore not explained in detail again.

FIG. 2C shows a schematic side view of an optoelectronic semiconductor chip 100 according to an embodiment. The semiconductor chip of FIG. 2C differs from the semiconductor chip of FIG. 2B in that the p-contact layer 9 and the current spreading layer 13 are broken through in a region. For example, during the production of the optoelectronic semiconductor chip 100, a recess is produced in the current spreading layer 13 and the p-contact layer 9 before the application of the dielectric layer 19 and the p-connecting contact 14. This structuring is performed in particular before the growth substrate is detached and before the semiconductor chip 100 is connected to the carrier substrate 161. This has the advantage that the current flow through the active region 20 is reduced. In this way it is achieved that less radiation is generated below the re-connecting contact 15 and thus absorption losses are reduced.

Otherwise, the exemplary embodiment in FIG. 2C corresponds to the embodiments of the semiconductor chip in FIG. 2B.

The semiconductor chip of FIGS. 2A to 2C was produced in particular at a temperature between 540° C. and 650° C., at a pressure between 30 mbar and 300 mbar and a ratio between second and first precursor of 5 to 150. The resulting layer thickness of the first layer 12 is in particular between 5 nm and 200 nm, preferably 5 nm to 35 nm.

FIGS. 3A to 3D each show a schematic side view of an optoelectronic semiconductor chip according to an embodiment. Here, the first layer 12 is formed in particular as a p-current spreading layer. In addition, the first layer 12 can have a p-contact function.

The semiconductor chip of FIG. 3A comprises an active region 20, which is arranged between an n-conducting region 21 and a p-conducting region 22.

The active region 20 is based on a phosphide compound semiconductor material. For example, the active region 20 is formed as a quantum structure with a plurality of quantum layers 201 and barrier layers 202 arranged between them. By selecting the material composition of the phosphide compound semiconductor material and/or the layer thickness of the quantum layers 201, the emission wavelength of the radiation to be generated in the active region 20 can be varied from the green, yellow, and red to the infrared spectral range.

The p-conducting region 22 comprises the first layer 12, which here is formed as a p-current spreading layer 6. The current spreading layer 6 is doped with carbon and comprises a phosphide compound semiconductor material, in particular C-doped GaP. The carbon doping concentration is in particular between 2×10¹⁹ and 3×10²⁰ cm⁻³.

All the definitions and explanations given so far for the first layer 12 also apply to the exemplary embodiment in FIG. 3A, which is therefore not explained in detail here.

The semiconductor chip of FIGS. 3A to 3D was produced in particular at a temperature between 540° C. and 660° C., at a pressure between 30 mbar and 300 mbar and a ratio between second and first precursor of 10 and 200. The resulting layer thickness of the first layer 12 is in particular between 50 nm and 500 nm, preferably 200 nm to 350 nm.

In particular, the current spreading layer 6 is free of aluminum and/or indium.

The current spreading layer 6 is characterized by a high transmission in the above-mentioned spectral range for the radiation to be generated in the active region 20. In addition, such a current spreading layer is more moisture stable compared to an aluminum gallium arsenide current spreading layer.

In contrast to the other layers of the semiconductor layer sequence 1, the current spreading layer 6 is completely or partially relaxed and therefore does not have the lattice constant of the growth substrate. All layers of the semiconductor layer sequence arranged on the side of the current spreading layer 6 facing the active region 20 therefore have the same lattice constant.

The p-conducting region 22 can further comprise a subregion 221 on the side of the current spreading layer 6 facing the active region 20. Subregion 221 is p-conductively doped by means of a second dopant. In particular, the second dopant is different from carbon. For example, the second dopant is magnesium.

FIG. 3B shows a semiconductor chip 100, which has a carrier 16. The carrier 16 is attached to the semiconductor layer sequence 1 by means of a connection layer 18, for example, a solder layer or an electrically conductive adhesive layer. A mirror layer 200 may be arranged between the carrier 16 and the semiconductor layer sequence 1. The mirror layer 200 is simultaneously used for electrically contacting the current spreading layer 6. The semiconductor chip 100 also comprises a p-conductive region 22, an active region 20 and an n-conductive region 21. In addition, the semiconductor chip 100 comprises a p-connecting contact 14 and an n-connecting contact 15. The n-connecting contact 15 adjoins the n-conducting region 21, the p-connecting contact 14 adjoins the carrier 16.

Other advantageous configurations and the resulting advantages of this exemplary embodiment essentially correspond to the exemplary embodiment in FIG. 3A.

In particular, the semiconductor chip according to FIG. 3B is formed as a volume emitter. This refers to a semiconductor chip in which a substantial part of the radiation, for example, at least 30% of the radiation, emerges from the side of the semiconductor chip.

FIG. 3C shows another exemplary embodiment of a semiconductor chip 100. This exemplary embodiment corresponds essentially to the exemplary embodiment described in conjunction with FIG. 3B.

In contrast to this, the current spreading layer 6 comprises a structuring in lateral direction. The structuring is formed in the form of a plurality of recesses 210 in the current spreading layer 6. The recesses 210 are provided, for example, for an interference of waveguide effects. The decoupling efficiency can thus be increased.

FIG. 3D shows another exemplary embodiment of a semiconductor body 100 according to an embodiment. This exemplary embodiment corresponds essentially to the exemplary embodiment described in conjunction with FIG. 3A. Contrary to this, the p-conducting region comprises a superlattice structure 220. The superlattice structure 220 is arranged between the current spreading layer 6 and the active region 20. For example, the superlattice structure 220 comprises a plurality of first sublayers 2210 and a plurality of second sublayers 2220. For a simplified representation, FIG. 3D shows only one first sublayer 2210 and one second sublayer 2220. Gallium phosphide is suitable for the first sublayer 2210 and aluminum indium phosphide for the second sublayer 2220.

By means of the superlattice structure 220, the risk of a continuation of lattice defects starting from the current spreading layer 6 towards the active region 20 can be largely reduced. The resulting loss of light can thus be avoided.

Overall, the semiconductor bodies described here and the semiconductor chip formed with them are characterized by high moisture stability, low light loss and, at the same time, good current spreading and/or p-contacting due to a high electrical conductivity with simultaneously low absorption losses. In addition, the reliability of the semiconductor chip can be improved due to improved adhesion of a dielectric layer on a current spreading layer.

The exemplary embodiments described in conjunction with the figures and their features can also be combined with each other according to further exemplary embodiments, even if such combinations are not explicitly shown in the figures.

Furthermore, the exemplary embodiments described in conjunction with the figures may have additional or alternative features according to the description in the general part.

The invention is not limited to the exemplary embodiments by the description. Rather, the invention comprises each feature as well as each combination of features, which in particular includes each combination of features in the patent claims, even if this feature or this combination itself is not explicitly indicated in the patent claims or exemplary embodiments.

The present patent application claims the priority of the German patent application DE 10 2017 123 542.6, the disclosure content of which is hereby incorporated by reference.

### REFERENCES

100 optoelectronic semiconductor chip

1 semiconductor layer sequence

2 surface of the semiconductor layer sequence

20 active region

21 n-conducting region

22 p-conducting region

3 first precursor

4 second precursor

31 III-compound material

41 phosphorus-containing compound material

5 chamber

6 phosphide compound semiconductor material

7 carrier gas

8 third precursor

9 p-contact layer

10 p-current spreading layer

11 by-product

12 first layer

13 current spreading layer

14 p-connecting contact

15 n-connecting contact

16 carrier

161 carrier substrate

17 p-InGaAlP layer

18 connection layer

19 dielectric layer

200 mirror layer

210 recesses

220 superlight structures

2210 first subregion

2220 second subregion

1. A method for producing an optoelectronic semiconductor chip comprising the steps:
A) providing a surface in a chamber,
B) providing at least one organic first precursor and one second precursor in the chamber, wherein the organic first precursor comprises a gaseous III-compound material, wherein the second precursor comprises a gaseous phosphorus-containing compound material,
C) epitaxial deposition of the first and the second precursor at a temperature between 540° C. inclusive and 660° C. inclusive and a pressure between 30 mbar inclusive and 300 mbar inclusive onto the surface in the chamber to form a first layer comprising a phosphide compound semiconductor material, wherein the ratio between the second and the first precursor is between 5 inclusive and 200 inclusive, wherein the phosphide compound semiconductor material produced is doped with carbon, wherein the carbon doping concentration is at least 4×10¹⁹ cm ⁻³ and wherein after step C) a cooling step is performed without the second precursor and only with a carrier gas.

2. The method according to claim 1, wherein after step C) a cooling step of at least the phosphide compound semiconductor material is performed in the chamber, wherein the chamber is free of the second precursor.

3. The method according to claim 1, wherein hydrogen is used as the carrier gas in step C).

4. The method according to claim 1, wherein additionally a gaseous organic third precursor CBr₄ is used.

5. The method according to claim 1, wherein the first layer comprises a layer thickness of 5 nm inclusive to 200 nm inclusive or of 50 nm inclusive to 500 nm inclusive.

6. The method according to claim 1, wherein the temperature in step C) is between 540° C. and 620° C. for a first layer formed as a p-contact layer or between 560° C. and 660° C. for a first layer formed as a p-current spreading layer.

7. The method according to claim 1, wherein the pressure in step C) is between 60 mbar and 70 mbar.

8. The method according to claim 1, wherein the carbon doping concentration is between 5×10¹⁹ cm⁻³ and 1×10²¹ cm⁻³ for a first layer formed as a p-contact layer or between 4×10¹⁹ cm⁻³ and 3×10²⁰ cm⁻³ for a first layer formed as a p-current spreading layer.

9. The method according to claim 1, wherein the ratio between the second and first precursor is between 5 inclusive and 150 inclusive or between 10 inclusive and 200 inclusive.

10. The method according to claim 1, wherein the organic first precursor and/or the III-compound material is trimethylgallium (TMGa), trimethylindium (TMIn) or trimethylaluminum (TMAl).

11. The method according to claim 1, wherein the second precursor and/or the phosphorus-containing compound material is phosphine (PH₃).

12. The method according to claim 1, wherein the epitaxial deposition in step C) is a metal organic vapor phase epitaxy (MOVPE).

13. The method according to claim 1, wherein the phosphide compound semiconductor material is a GaP or AlGaP.

14. The method according to claim 1, wherein the surface is the surface of a semiconductor layer sequence comprising an active region provided for generating radiation, an n-conducting region and a p-conducting region, wherein the active region is arranged between the n-conducting region and the p-conducting region.

15. The method according to claim 1, wherein the first layer directly adjoins the surface of a semiconductor layer sequence and is formed as a p-contact layer and/or a p-current spreading layer.

16. An optoelectronic semiconductor chip with
a semiconductor layer sequence comprising a carbon-doped phosphide compound semiconductor material and having an active region provided for generating radiation, an n-conducting region and a p-conducting region, wherein
the active region is arranged between the n-conducting region and the p-conducting region,
the p-conducting region comprises a first layer or the first layer adjoins the p-conducting region, wherein the first layer is based on the carbon doped phosphide compound semiconductor material, wherein the carbon doping concentration is at least 5×10¹⁹ cm⁻³, wherein the first layer is formed as a p-contact layer and p-current spreading layer.

17. The optoelectronic semiconductor chip according to claim 16,
wherein the thickness of the first layer is between 5 nm and 200 nm.

18. The optoelectronic semiconductor chip according to claim 16, wherein a dielectric layer is arranged in regions between the current spreading layer and the p-connecting contact.

19. An optoelectronic semiconductor chip with
a semiconductor layer sequence comprising a carbon-doped phosphide compound semiconductor material and having an active region provided for generating radiation, an n-conducting region and a p-conducting region, wherein
the active region is arranged between the n-conducting region and the p-conducting region,
the p-conducting region comprises a first layer or the first layer adjoins the p-conducting region, wherein the first layer is based on the carbon doped phosphide compound semiconductor material, wherein the carbon doping concentration is at least 5×10¹⁹ cm⁻³, wherein the first layer is formed as a p-contact layer and p-current spreading layer, wherein the p-contact layer and the current spreading layer are broken through in a region.
